(19) United States
(12) Patent Application Publication
(10) Pub. No.: US 2019/0310435 A1
(43) Pub. Date: Oct. 10, 2019

(54) COMMUNICATION MODULE

(71) Applicant: Fujitsu Component Limited, Tokyo (JP)

(72) Inventors: Shinichiro Akieda, Tokyo (JP); Osamu Daikuhara, Tokyo (JP)

(21) Appl. No.: 16/376,309

(22) Filed: Apr. 5, 2019

(30) Foreign Application Priority Data
Apr. 10, 2018 (JP) 2018-075217

(51) Int. Cl. G02B 6/42; H05K 1/18; H05K 7/20

(52) U.S. Cl. CPC G02B 6/4269; G02B 6/4281; H05K 1/189; H05K 2201/10522; G02B 6/4262; H05K 2201/10121; H05K 7/20445

(57) ABSTRACT

A communication module includes a housing, a circuit board in the housing, a heating element on the circuit board, and a heat dissipating member sandwiched between the inside surface of the housing and the heating element. The inside surface includes protrusions protruding toward the heating element.

### CROSS-REFERENCE TO RELATED APPLICATION

The present application is based on and claims priority to Japanese patent application No. 2018-075217, filed on Apr. 10, 2018, the entire contents of which are incorporated herein by reference.

### BACKGROUND OF THE INVENTION

### 1. Field of the Invention

The present invention relates to communication modules.

### 2. Description of the Related Art

Communication devices of supercomputers or the like use optical communications to enable high-speed transmission of large-capacity communication data.

In optical communications, an optical module is used to connect an optical cable to a communication device. The optical module converts an optical signal into an electrical signal, and coverts an electrical signal into an optical signal.

The optical module includes a light-emitter, a driver that drives the light-emitter, a light-receiver, and a transimpedance amplifier (TIA) that converts an electric current signal into a voltage signal.

Devices such as a driver and a TIA operate to generate heat. Therefore, for a stable operation of the optical module, it is desired to reduce generation of heat by heating elements. To reduce generation of heat by heating elements, a heat dissipating member is provided between a heating element and a housing to transfer heat from the heating element to the housing to dissipate the heat outside the housing. See Japanese Laid-open Patent Publication No. 2008-306064.

### SUMMARY OF THE INVENTION

According to an aspect of the present invention, a communication module includes a housing, a circuit board in the housing, a heating element on the circuit board, and a heat dissipating member sandwiched between the inside surface of the housing and the heating element. The inside surface includes protrusions protruding toward the heating element.

### BRIEF DESCRIPTION OF THE DRAWINGS

FIGS. 1 and 2 are an exploded perspective view and a partial enlarged view, respectively, of an optical module according to an embodiment;

FIG. 3 is a diagram illustrating the inside surface of an upper casing of the optical module according to the embodiment;

FIG. 4 is a diagram illustrating protrusions according to the embodiment;

FIG. 5 is a cross-sectional view of the optical module according to the embodiment;

FIG. 6 is a diagram illustrating protrusions according to a first variation;

FIG. 7 is a cross-sectional view of the optical module according to the first variation;

FIG. 8 is a diagram illustrating protrusions according to a second variation;

FIG. 9 is a cross-sectional view of the optical module according to the second variation;

FIG. 10 is a diagram illustrating protrusions according to a third variation;

FIG. 11 is a cross-sectional view of the optical module according to the third variation;

FIG. 12 is a diagram illustrating protrusions according to a fourth variation;

FIG. 13 is a cross-sectional view of the optical module according to the fourth variation;

FIG. 14 is a diagram illustrating protrusions according to a fifth variation;

FIG. 15 is a cross-sectional view of the optical module according to the fifth variation;

FIG. 16 is a diagram illustrating protrusions according to a sixth variation;

FIG. 17 is a cross-sectional view of the optical module according to the sixth variation;

FIG. 18 is a diagram illustrating protrusions according to a seventh variation;

FIG. 19 is a cross-sectional view of the optical module according to the seventh variation;

FIG. 20 is a graph illustrating the characteristic of a load on a heating element according to examples; and

FIG. 21 is a table illustrating the temperature characteristic of the heating element according to the examples.

### DESCRIPTION OF THE EMBODIMENTS

According to JP 2008-306064, a metal casing includes multiple protrusions and depressions that are closely formed where the metal casing contacts a thermally conductive sheet, and presses the thermally conductive sheet with the protrusions. Because of the pointed ends of the protrusions, a vertical pressure is horizontally distributed to reduce mechanical stress on an electronic component. However, J P 2008-306064 focuses only on reduction in mechanical stress, and does not simultaneously attempt to further improve the heat dissipation efficiency of the electronic component.

According to an aspect of the present invention, a communication module that can improve the efficiency of heat dissipation through a heat dissipating member while reducing a load applied to a heating element from a housing is provided.

An embodiment is described below with reference to the drawings. In the following description, a Z direction, an X direction, and a Y direction in the drawings are referred to as a vertical direction, a longitudinal direction, and a lateral direction, respectively.

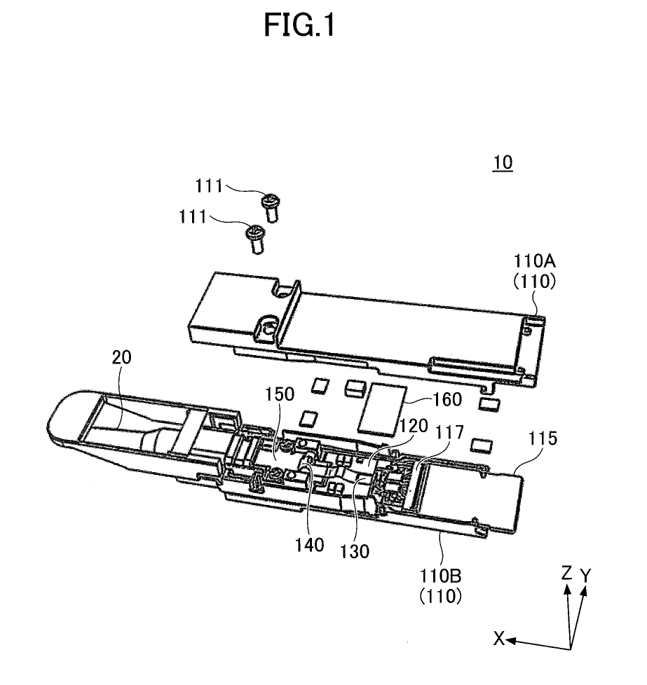

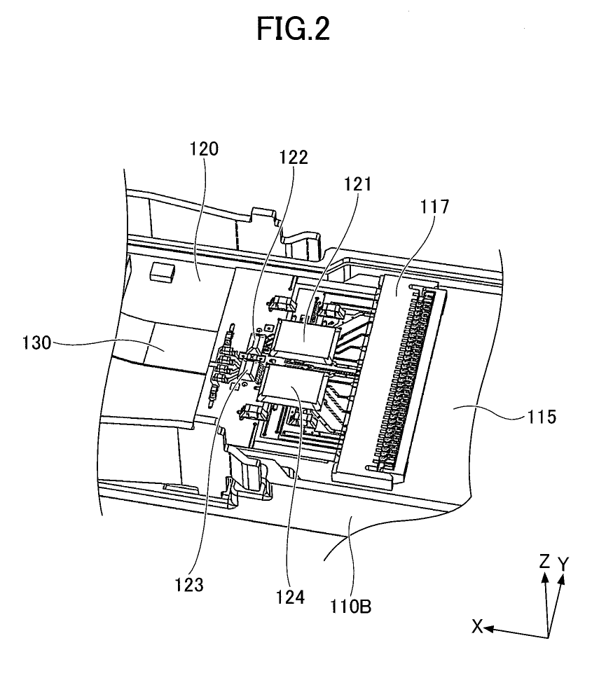

FIGS. 1 and 2 are an exploded perspective view and a partial enlarged view, respectively, of the optical module 10 according to the embodiment. The optical module 10 is an example of a communication module. The optical module 10 is a device attached to an optical cable 20 to connect the optical cable 20 to a communication device of, for example, a supercomputer. By connecting the optical module 10 to the communication device, optical signals can be transmitted to and received from the communication device. The optical module 10 converts an electrical signal output from the communication device into an optical signal, and transmits the optical signal to the optical cable 20. The optical module 10 converts an optical signal transmitted from the optical cable 20 into an electrical signal, and outputs the electrical signal to the communication device.

Referring to FIG. 1, the optical module 10 includes a housing 110, a printed circuit board 115, a flexible printed circuit (FPC) 120, an optical waveguide 130, a ferrule 140, a clip 150, and a heat dissipating sheet 160.

The housing 110 is a vertically thin box-shaped member having a substantially parallelepiped shape. A metal material such as an aluminum or zinc die casting is used for the housing 110. The housing 110 includes an upper casing 110A and a lower casing 110B that are separable from each other. The casing 110B is a member that is open on the upper side. The casing 110A is a lid-shaped member that closes the opening of the casing 110B. The board 115, the FPC 120, and the sheet 160 are incorporated into the housing 110. The optical cable 20 extends from a first end of the housing 110. The board 115 is exposed at a second end of the housing 110. The casing 110A and the casing 110B are fixedly coupled with screws 111.

The board 115 is provided at an end of the casing 110B. The board 115 lies between the communication device and the FPC 120. The FPC 120 is electrically connected to a connector 117 provided on the board 115.

The FPC 120 is a circuit board constituting an electronic circuit that implements the functions of the optical module 10. Circuit parts are mounted on the FPC 120. The FPC 120 is a film-shaped member having interconnects sandwiched between resin materials such as polyimide. Referring to FIG. 2, a driver 121, a light-emitter (emitter) 122, a light-receiver (receiver) 123, and a TIA 124 are mounted on the FPC 120.

The driver 121 is an integrated circuit (IC) that drives the emitter 122 in accordance with an electrical signal input from the communication device. The emitter 122 is driven by the driver 121 to emit laser light according to the input electrical signal. A vertical-cavity surface-emitting laser (VCSEL) may be used as the emitter 122. The emitted laser light is guided to the optical cable 20 via the optical waveguide 130.

The receiver 123 receives laser light from the optical cable 20 via the optical waveguide 130, and outputs a current signal commensurate with the amount of received light. A photodiode (PD) may be used as the receiver 123. The TIA 124 is an IC that converts the output current signal of the receiver 123 into a voltage signal, and outputs the voltage signal to the communication device via the board 115.

The TIA 124 and the driver 121, which are examples of heating elements, are laterally arranged on the FPC 120. The TIA 124 and the driver 121 have respective horizontal flat surfaces. Heat emitted from the TIA 124 and the driver 121 is transferred to the housing 110 via the sheet 160 to be dissipated outside the housing 110.

The optical waveguide 130 is formed of a flexible film formed of a polymer such as polyimide in which cores for propagating laser light are formed. The optical waveguide 130 is connected to the FPC 120 and the ferrule 140.

The ferrule 140 includes a lens ferrule with lenses connected to the optical waveguide 130 and a mechanically transferable (MT) ferrule connected to the optical cable 20. The ferrule 140 is fastened to the casing 110B by the clip 150 with an end face of the lens ferrule and an end face of the MT ferrule butted against each other.

The sheet 160 is an example of a heat dissipating member, and is held between an inside surface 110Aa of the casing 110A and each of the driver 121 and the TIA 124. The sheet 160 dissipates the heat of the driver 121 and the TIA 124 via the housing 110. A material such as silicon is used for the sheet 160.

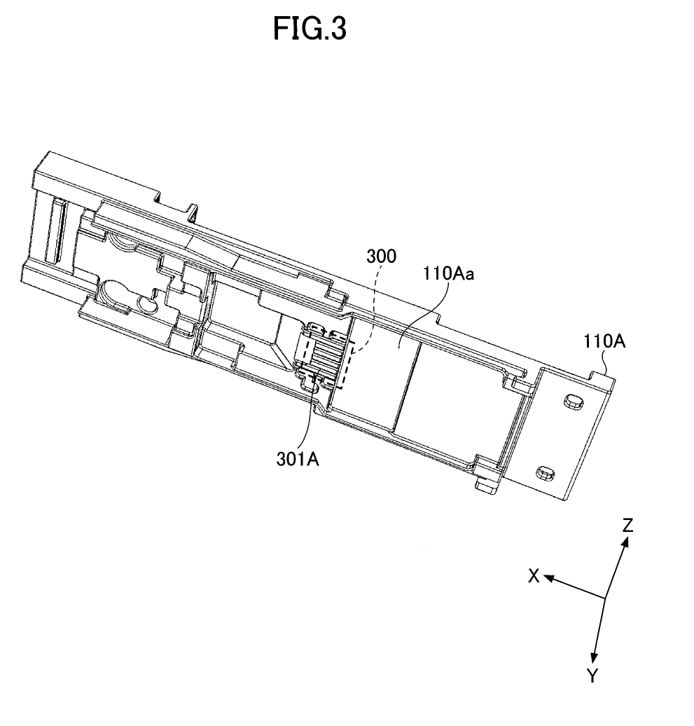

FIG. 3 is a diagram illustrating the surface 110Aa. The sheet 160 is held between each of the driver 121 and the TIA 124 and a region 300 of the surface 110Aa that faces the driver 121 and the TIA 124. Protrusions 301A protruding toward the driver 121 and the TIA 124 are formed at regular intervals in the region 300, that is, gaps formed one between each adjacent two of the protrusions 301A are uniform in width. The protrusions 301A are integrally formed with the casing 110A by forming the casing 110A using a mold in which shapes complementary to the shapes of the protrusions 301A are formed.

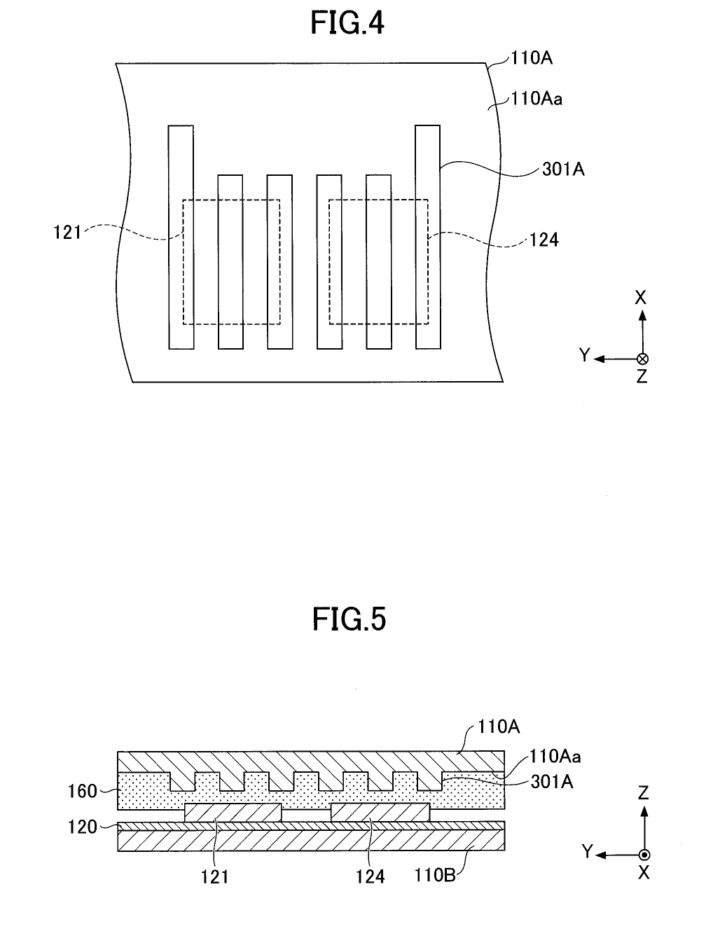

FIG. 4 is a diagram illustrating the protrusions 301A. The protrusions 301A are formed in the surface 110Aa in such a manner as to overlap the driver 121 and the TIA 124 in a plan view. Each protrusion 301A has a quadrangular prism shape, and the top of each protrusion 301A has a rectangular planar shape elongated in the longitudinal direction. By way of example, the six protrusions 301A are laterally arranged at regular intervals in FIG. 4.

FIG. 5 is a cross-sectional view of the optical module 10, illustrating its heat dissipation structure. When the casings 110A and 110B are joined, the sheet 160 is pressed and fills in the gap between the casing 110A and each of the driver 121 and the TIA 124. A part of the casing 110A that applies a load on the sheet 160 is in particular the top planar surface of each protrusion 301A. According to the configuration of FIG. 5 where the protrusions 301A are placed at regular intervals, the area of the casing 110A that applies a load on the sheet 160 can be reduced compared with the case where the entirety of the surface 110Aa with no protrusions provided thereon applies a load on the sheet 160. Therefore, according to FIG. 5, a load applied onto the driver 121 and the TIA 124 from the casing 110A via the sheet 160 can be reduced.

Furthermore, according to the configuration of FIG. 5, the surface area of the surface 110Aa can be increased by the protrusions 301A. Further, the top ends of the protrusions 301A can be brought closer to the driver 121 and the TIA 124 while reducing a load applied on the driver 121 and the TIA 124, so that the distance between the casing 110A and the driver 121 and the TIA 124 can be reduced compared with the case of providing no protrusions in the surface 110Aa. Therefore, heat emitted from the driver 121 and the TIA 124 is more likely to be transferred to the casing 110A, so that the heat dissipation efficiency can be improved.

In particular, according to the configuration of FIG. 5, the top of each protrusion 301A has a planar shape having a certain area. Therefore, the area of the top of each protrusion 301A, which is closest to the driver 121 and the TIA 124, can be increased, so that a sufficient surface area for transferring heat emitted from the driver 121 and the TIA 124 to the casing 110A can be ensured. Accordingly, the efficiency of dissipating heat from the driver 121 and the TIA 124 can be improved.

### [Variations]

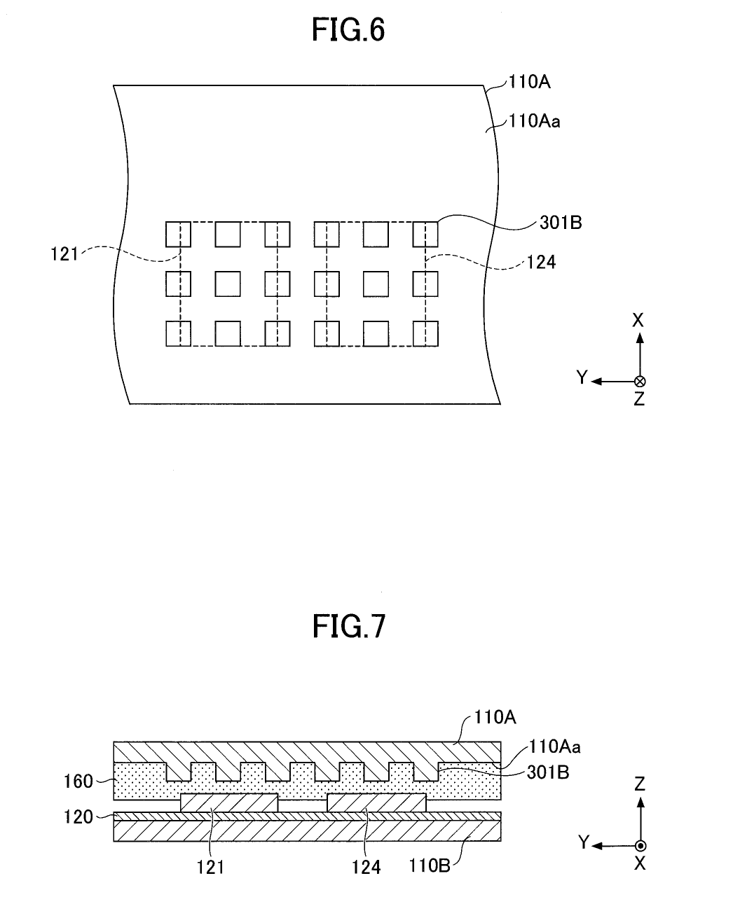

Variations of the protrusions 301A are described with reference to FIGS. 6 through 19.

### [First Variation]

FIG. 6 is a diagram illustrating protrusions 301B according to a first variation. The protrusions 301B are formed in the surface 110Aa in such a manner as to overlap the driver 121 and the TIA 124 in a plan view. Each protrusion 301B has a quadrangular prism shape, and has a square top. The protrusions 301B are arranged at regular intervals in longitudinal and lateral arrays. Eighteen protrusions 301B are arranged in a 3×6 matrix in FIG. 6.

FIG. 7 is a cross-sectional view of the optical module 10 according to the first variation. According to the first variation, when the casings 110A and 110B are joined, the top surface of each protrusion 301B in particular applies a load onto the sheet 160.

According to the first variation, the area of the casing 110A that applies a load on the sheet 160 can be reduced, so that a load applied onto the driver 121 and the TIA 124 from the casing 110A via the sheet 160 can be reduced compared with the case of providing no protrusions in the surface 110Aa.

The protrusions 301B can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

In FIG. 7, the top of each protrusion 301B has a planar shape having a certain area. Therefore, a sufficient surface area for transferring heat emitted from the driver 121 and the TIA 124 to the casing 110A can be ensured at a position closer to the driver 121 and the TIA 124, so that the efficiency of dissipating heat from the driver 121 and the TIA 124 can be improved.

### [Second Variation]

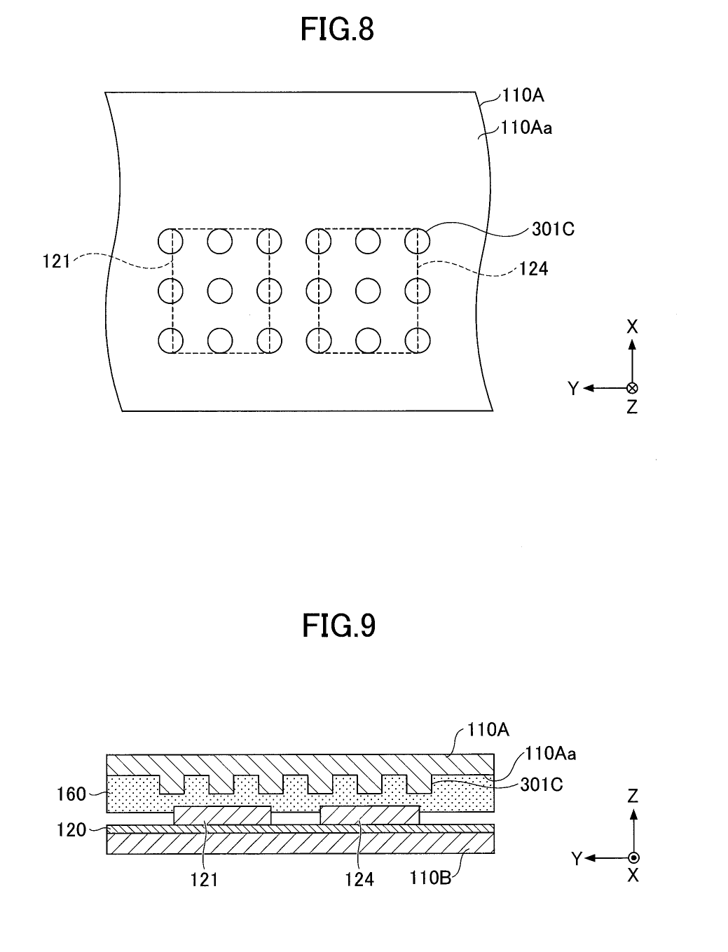

FIG. 8 is a diagram illustrating protrusions 301C according to a second variation. The protrusions 301C are formed in the surface 110Aa in such a manner as to overlap the driver 121 and the TIA 124 in a plan view. Each protrusion 301C has a circular cylindrical shape and a circular top planar surface. The number of the protrusions 301C and their arrays are the same as in the first variation.

FIG. 9 is a cross-sectional view of the optical module 10 according to the second variation. According to the second variation, the top surface of each protrusion 301C applies a load onto the sheet 160 when the casings 110A and 110B are joined. Therefore, compared with the case of providing no protrusions in the surface 110Aa, the area of the casing 110A that applies a load on the sheet 160 can be reduced, so that a load applied onto the driver 121 and the TIA 124 from the casing 110A can be reduced.

Furthermore, according to the second variation, the protrusions 301C can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

In FIG. 9, the top of each protrusion 301C has a planar shape having a certain area. Therefore, a sufficient surface area for transferring heat emitted from the driver 121 and the TIA 124 to the casing 110A can be ensured at a position closer to the driver 121 and the TIA 124, so that the efficiency of dissipating heat from the driver 121 and the TIA 124 can be improved.

### [Third Variation]

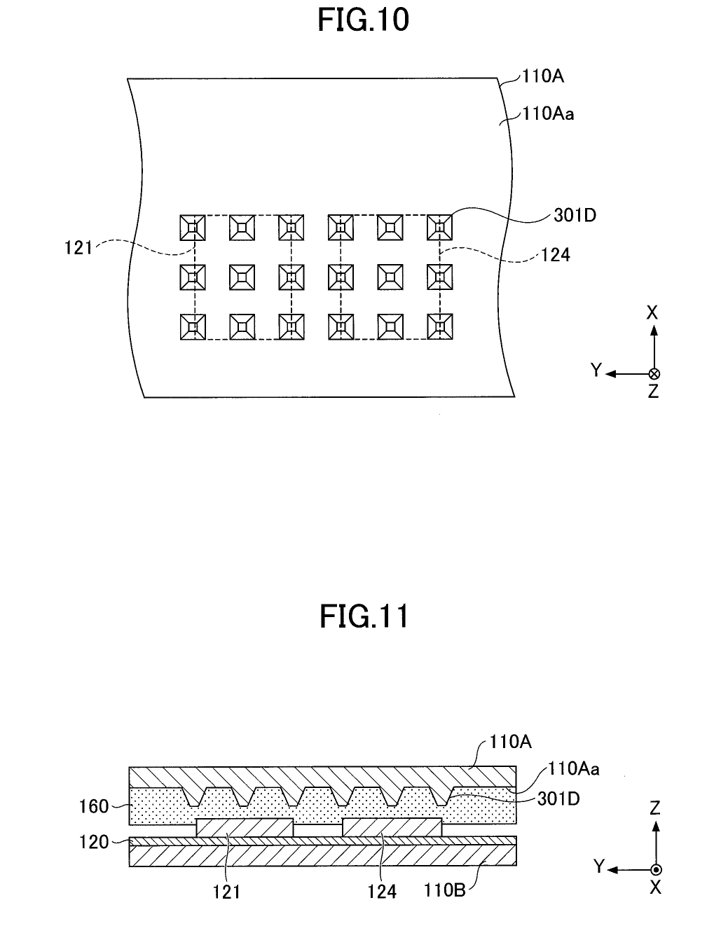

FIG. 10 is a diagram illustrating protrusions 301D according to a third variation. The protrusions 301D are formed in the surface 110Aa in such a manner as to overlap the driver 121 and the TIA 124 in a plan view. Each protrusion 301D has a truncated pyramid shape and a square top planar surface. The number of the protrusions 301D and their arrays are the same as in the first variation.

FIG. 11 is a cross-sectional view of the optical module 10 according to the third variation. According to the third variation, when the casings 110A and 110B are joined, the top planar surface of each protrusion 301D in particular applies a load onto the sheet 160. Therefore, according to the third variation, the area of the casing 110A that applies a load on the sheet 160 can be reduced compared with the case of providing no protrusions in the surface 110Aa, so that a load applied onto the driver 121 and the TIA 124 from the casing 110A via the sheet 160 can be reduced.

According to the third variation, the protrusions 301D can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

According to the third variation, the top of each protrusion 301D has a planar shape having a certain area. Therefore, a sufficient surface area for transferring heat emitted from the driver 121 and the TIA 124 to the casing 110A can be ensured at a position closer to the driver 121 and the TIA 124, so that the heat dissipation efficiency can be improved.

### Fourth Embodiment

FIG. 12 is a diagram illustrating protrusions 301E according to a fourth variation. The protrusions 301E are formed in the surface 110Aa in such a manner as to overlap the driver 121 and the TIA 124 in a plan view. Each protrusion 301E has a truncated cone shape and a circular top planar surface. The number of the protrusions 301E and their arrays are the same as in the first variation.

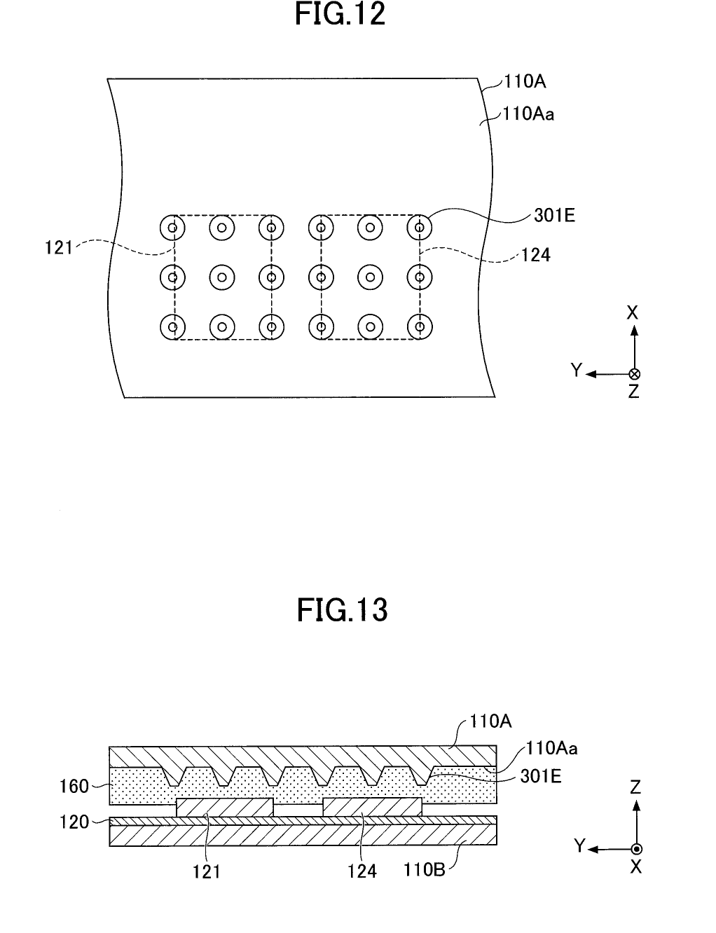

FIG. 13 is a cross-sectional view of the optical module 10 according to the fourth variation. According to the fourth variation, when the casings 110A and 110B are joined, the top of each protrusion 301E in particular applies a load onto the sheet 160. Therefore, according to the fourth variation, the area of the casing 110A that applies a load on the sheet 160 can be reduced compared with the surface 110Aa with no protrusions, so that a load applied onto the driver 121 and the TIA 124 from the casing 110A via the sheet 160 can be reduced.

Furthermore, according to the fourth variation, the protrusions 301E can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

According to the fourth variation, the top of each protrusion 301E has a planar shape having a certain area. Therefore, a sufficient surface area for transferring heat emitted from the driver 121 and the TIA 124 to the casing 110A can be ensured at a position closer to the driver 121 and the TIA 124. Thus, according to the configuration of FIG. 13, the efficiency of dissipating heat from the driver 121 and the TIA 124 can be improved.

The protrusions of the optical module 10 are not limited to a shape having a planar surface at their top. The following fifth through seventh variations discuss the cases of using protrusions having a shape other than a planar surface at their top in the optical module 10.

### [Fifth Variation]

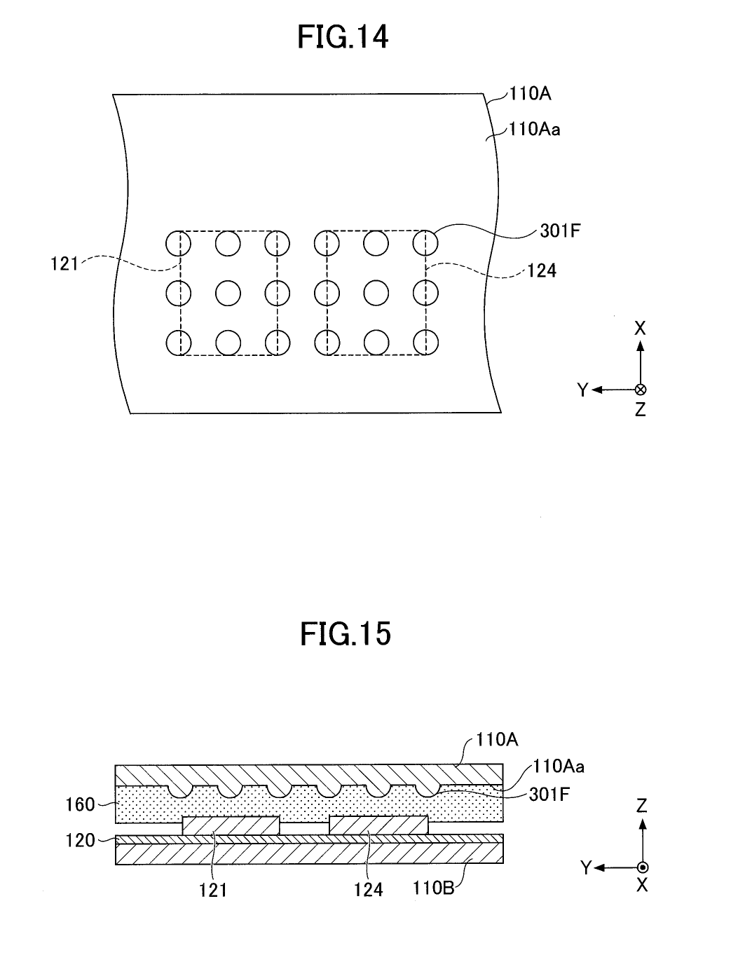

FIG. 14 is a diagram illustrating protrusions 301F according to the fifth variation. The hemispherical protrusions 301F are formed in the surface 110Aa in such a manner as to overlap the driver 121 and the TIA 124 in a plan view. The number of the protrusions 301F and their arrays are the same as in the first variation.

FIG. 15 is a cross-sectional view of the optical module 10 according to the fifth variation. According to the fifth variation, the protrusions 301F apply a load onto the sheet 160 when the casings 110A and 110B are joined. Therefore, according to the fifth variation, the area of the casing 110A that applies a load on the sheet 160 can be reduced compared with the surface 110Aa with no protrusions, so that a load applied onto the driver 121 and the TIA 124 from the casing 110A via the sheet 160 can be reduced.

Furthermore, according to the fifth variation, the protrusions 301F can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

### [Sixth Variation]

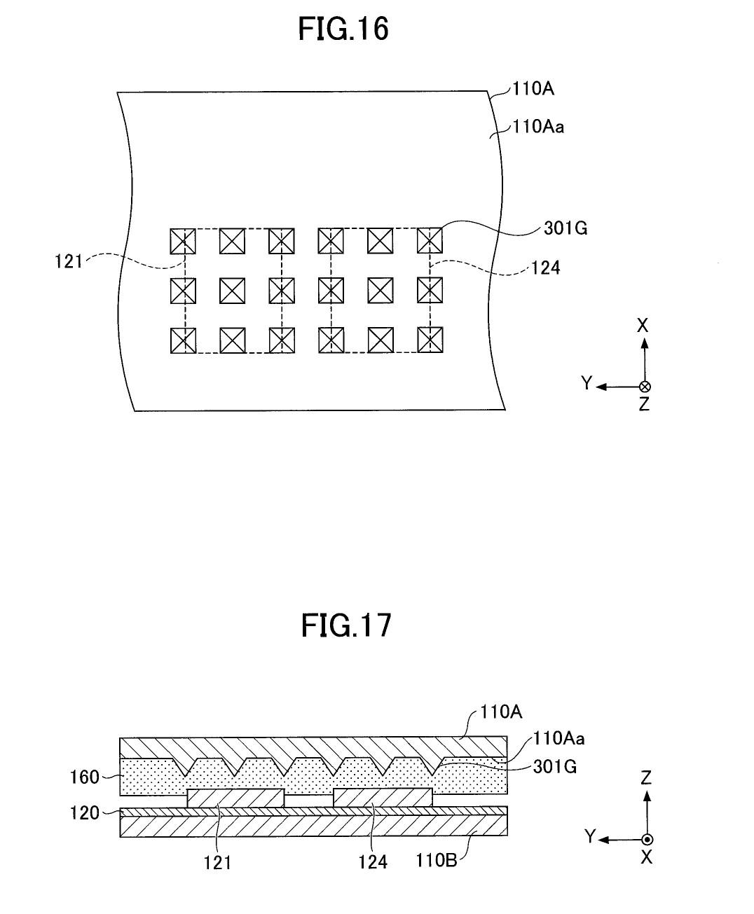

FIG. 16 is a diagram illustrating protrusions 301G according to the sixth variation. The pyramidal protrusions 301G are formed in the surface 110Aa in such a manner as to overlap the driver 121 and the TIA 124 in a plan view. The number of the protrusions 301G and their arrays are the same as in the first variation.

FIG. 17 is a cross-sectional view of the optical module 10 according to the sixth variation. In the sixth variation, the protrusions 301G apply a load onto the sheet 160 when the casings 110A and 110B are joined. According to the sixth variation, the area of the casing 110A that applies a load on the sheet 160 can be reduced compared with the surface 110Aa with no protrusions, so that a load applied onto the driver 121 and the TIA 124 from the casing 110A via the sheet 160 can be reduced.

Furthermore, according to the sixth variation, the protrusions 301G can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the heat dissipation efficiency can be improved.

### [Seventh Variation]

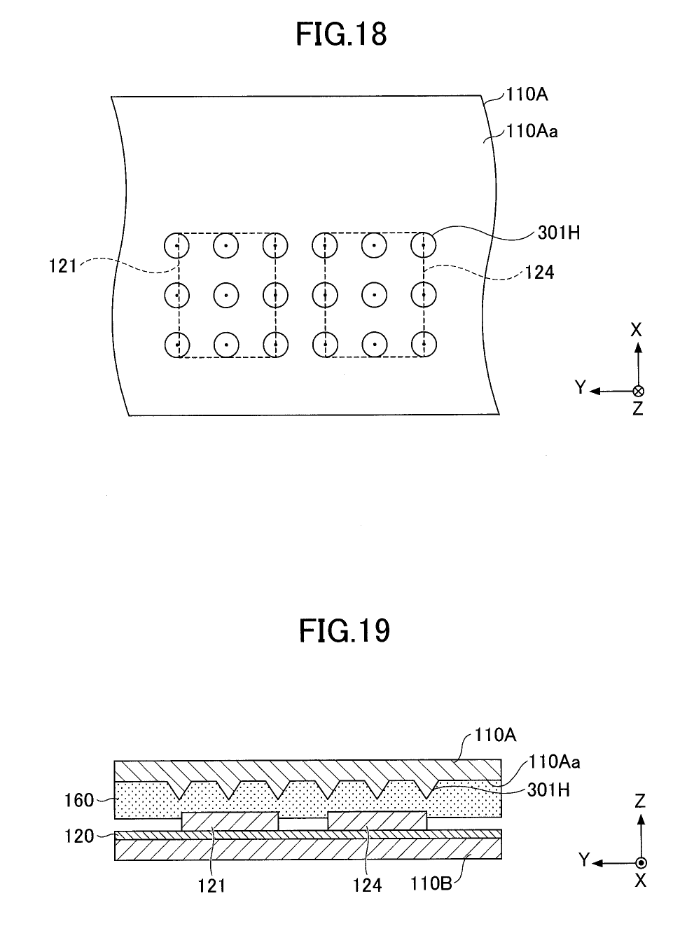

FIG. 18 is a diagram illustrating protrusions 301H according to the seventh variation. The conical protrusions 301H are formed in the surface 110Aa in such a manner as to overlap the driver 121 and the TIA 124 in a plan view. The number of the protrusions 301H and their arrays are the same as in the first variation.

FIG. 19 is a cross-sectional view of the optical module 10 according to the seventh variation. According to the seventh variation, the protrusions 301H apply a load onto the sheet 160 when the casings 110A and 110B are joined. Therefore, according to the seventh variation, the area of the casing 110A that applies a load on the sheet 160 can be reduced compared with the surface 110Aa with no protrusions, so that a load applied onto the driver 121 and the TIA 124 from the casing 110A via the sheet 160 can be reduced.

According to the seventh variation, the protrusions 301H can increase the surface area of the surface 110Aa, and reduce the shortest distance between the casing 110A and each of the driver 121 and the TIA 124. Therefore, heat emitted from the driver 121 and the TIA 124 is more likely to be transferred to the casing 110A, so that the efficiency of dissipating heat from the driver 121 and the TIA 124 can be improved.

### EXAMPLES

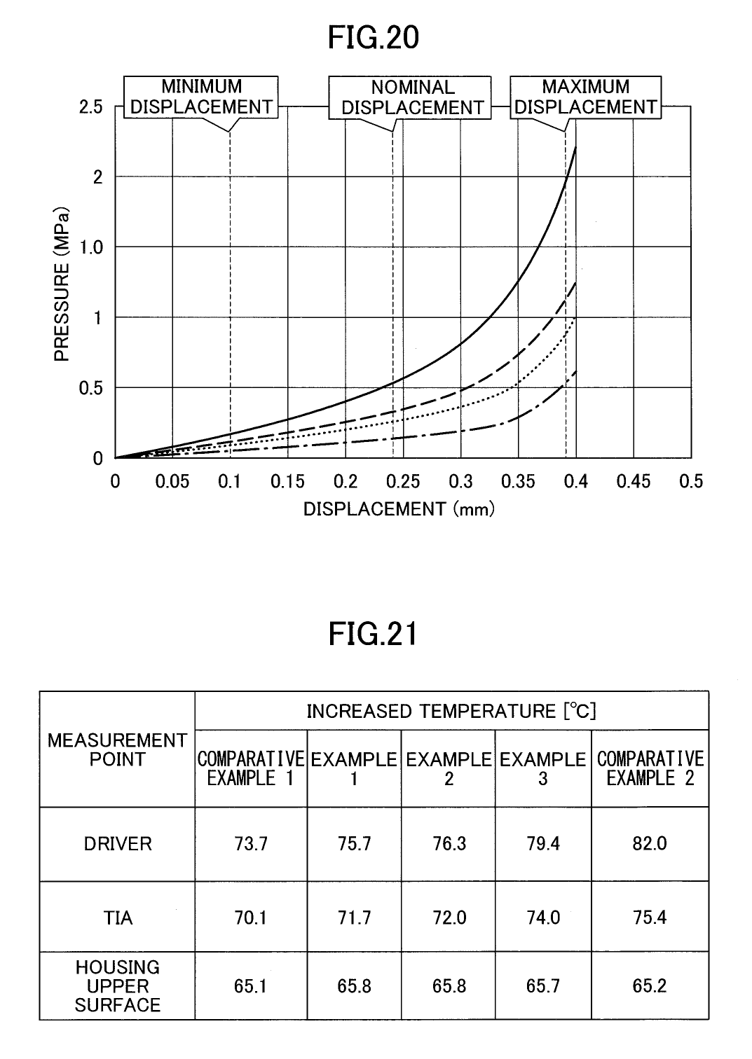

Examples of the optical module 10 are described below with reference to FIGS. 20 and 21. Specifically, with respect to Examples 1 through 3 and Comparative Examples 1 and 2 as set forth below, the sheet 160 was interposed between the casing 110A and each of the driver 121 and the TIA 124 which are the heating element, and a load on the heating element and the increased temperature of the heating element were measured.

### Examples 1 Through 3

In Examples 1 through 3, the protrusions 301B having a quadrangular prism shape according to the first variation are provided in the surface 110Aa. According to Example 1, the total area of the surface of the protrusions 301B contacting the heating element via the sheet 160 is 60% of the area of the surface 110Aa. According to Example 2, the total area of the surface of the protrusions 301B contacting the heating element via the sheet 160 is 50% of the area of the surface 110Aa. According to Example 3, the total area of the surface of the protrusions 301B is 25% of the area of the surface 110Aa.

### Comparative Examples 1 and 2

In Comparative Examples 1 and 2, no protrusions are provided in the surface 110Aa. According to Comparative Example 1, the surface 110Aa is brought close to the heating element with the casings 110A and 110B being joined. According to Comparative Example 2, the surface 110Aa is not brought close to the heating element with the casings 110A and 110B being joined.

### [Implementation Results: Load Characteristic]

FIG. 20 is a graph illustrating the characteristic of a load on the heating element. In FIG. 20, the solid line, the dashed line, the dotted line, and the one-dot chain line indicate load characteristics according to Comparative Example 1, Example 1, Example 2, and Example 3, respectively.

As illustrated in FIG. 20, according to Examples 1 through 3, a load on the heating element can be lower than in Comparative Example 1 irrespective of the amount of displacement. In particular, according to Examples 1 through 3, a decrease in the load on the heating element can be increased as the amount of displacement increases, compared with Comparative Example 1. Furthermore, according to Examples 1 through 3, the load on the heating element can be reduced as the total area of the planar surface contacting the heating element decreases.

For example, when the target value of a load on the heating element at nominal displacement is 0.5 MPa, the load on the heating element according to Comparative Example 1 is 0.54 MPa, which exceeds the target value.

In contrast, according to Examples 1 through 3, their loads on the heating element are 0.32 MPa, 0.26 MPa, and 0.14 MPa, respectively, which are lower than the target value.

According to the optical module 10, a load on a heating element can be easily controlled to a target value by adjusting at least one of the number, installation position, installation interval, shape, and size of the protrusions 301B.

### [Implementation Results: Temperature Characteristic]

FIG. 21 is a table illustrating the temperature characteristic of the heating element. As illustrated in FIG. 21, the increased temperature of the heating element was measured with respect to each of Examples 1 through 3 and Comparative Examples 1 and 2. The increased temperature was measured at the driver 121, the TIA 124, and the upper surface of the casing 110A.

As illustrated in FIG. 21, the increased temperature of the heating element can be lower in Examples 1 through 3 than in Comparative Example 2. In particular, according to Examples 1 through 3, the increased temperature of the heating element can be lowered as the total area of the planar surface contacting the heating element increases.

According to Comparative Example 2, the increased temperature of the driver 121 is 82.0° C. and the increased temperature of the TIA 124 is 75.4° C. In contrast, according to Example 1, the increased temperature of the driver 121 is 75.7° C. and the increased temperature of the TIA 124 is 71.7° C., and the heat dissipation efficiency can be better than in Comparative Example 2. According to Example 2, the increased temperature of the driver 121 is 76.3° C. and the increased temperature of the TIA 124 is 72.0° C., and the heat dissipation efficiency can be better than in Comparative Example 2. According to Example 3, the increased temperature of the driver 121 is 79.4° C. and the increased temperature of the TIA 124 is 74.0° C., and the heat dissipation efficiency can be better than in Comparative Example 2.

According to the optical module 10, the increased temperature of a heating element can be easily controlled to a target temperature by adjusting at least one of the number, installation position, installation interval, shape, and size of the protrusions 301B.

Although the one or more embodiments of the present invention have been described heretofore, the present invention is not limited to these embodiments, and various variations and modifications may be made without departing from the scope of the present invention.

For example, the number, position, interval, shape, and size of protrusions are not limited to those described in the embodiment.

While the above-described embodiment illustrates an optical module, embodiments of the present invention may also be applied to any types of communication modules.

The present invention may also be applied to heating elements other than a driver or a TIA. Furthermore, embodiments of the present invention may use any heat dissipating member other than a heat dissipating sheet.

What is claimed is:

1. A communication module comprising:
a housing;
a circuit board in the housing;
a heating element on the circuit board; and
a heat dissipating member sandwiched between an inside surface of the housing and the heating element,
wherein the inside surface includes a plurality of protrusions protruding toward the heating element.

2. The communication module as claimed in claim 1, wherein the protrusions are formed at regular intervals.

3. The communication module as claimed in claim 1, wherein each of the protrusions has a planar top.

4. The communication module as claimed in claim 1, wherein each of the protrusions has a rounded top.
